(19) United States
(12) Patent Application Publication
(10) Pub. No.: US 2023/0344385 A1
(43) Pub. Date: Oct. 26, 2023

(54) BROADBAND TERAHERTZ FOURTH-HARMONIC MIXER CIRCUIT, MIXER AND METHOD

(71) Applicant: CEYEAR TECHNOLOGIES CO., LTD., Qingdao, Shandong (CN)

(72) Inventors: Jianqin DENG, Qingdao (CN); Fushun NIAN, Qingdao (CN); Wanshun JIANG, Qingdao (CN); Mo WANG, Qingdao (CN); Xiang ZHU, Qingdao (CN); Haiming XIN, Qingdao (CN); Dinghong JIA, Qingdao (CN); Shengzhou ZHANG, Qingdao (CN); Zhuo CHEN, Qingdao (CN)

(73) Assignee: CEYEAR TECHNOLOGIES CO., LTD., Qingdao, Shandong (CN)

(21) Appl. No.: 18/022,406

(22) PCT Filed: Nov. 6, 2020
(86) PCT No.: PCT/CN2020/127188

§ 371 Date: Feb. 21, 2023

(30) Foreign Application Priority Data
Aug. 18, 2020 (CN) 2020108333107

(51) Int. Cl. H03D 7/16; H03B 1/00

(52) U.S. Cl. CPC H03D 7/16; H03B 1/00; H03B 2200/0084

(57) ABSTRACT

A broadband terahertz fourth-harmonic mixer circuit, a mixer and a method wherein the broadband terahertz fourth-harmonic mixer circuit includes a radio frequency signal coupled transmission unit, nonlinear device, local oscillator filter, local oscillator signal coupled transmission unit and intermediate frequency filter unit which are sequentially connected; and further includes a radio frequency input port, local oscillator input port and intermediate frequency output port, where the radio frequency input port is connected to the radio frequency signal coupled transmission unit, the local oscillator input port is connected to the local oscillator signal coupled transmission unit, the intermediate frequency output port is connected to an output end of the intermediate frequency filter unit, and the local oscillator filter is of a two-level cascaded filter structure.

### TECHNICAL FIELD

The present disclosure relates to the technical field of mixers, and more particularly to a broadband terahertz fourth-harmonic mixer circuit, a mixer and a method.

### BACKGROUND

The description in this section merely provides background art related to the present disclosure, and does not necessarily constitute the prior art.

A terahertz harmonic mixer based on a Schottky diode is widely applied to many fields such as terahertz test instruments, communication and weather remote sensing. However, a terahertz balanced even harmonic mixer not only has a good frequency conversion character, but also does not need a balun structure, which makes a circuit structure simple and easy to integrate, thereby becoming one of preferred schemes of a terahertz receiver. How to increase the bandwidth of the terahertz even harmonic mixer and reduce frequency conversion loss and a noise coefficient becomes a to-be-solved key technical problem for the terahertz even harmonic mixer.

A harmonic mixing technology can effectively reduce needed local oscillator drive frequency. When n^{th} harmonic mixing is adopted, the needed local oscillator drive frequency is 1/n of the fundamental wave mixing local oscillator frequency, which can greatly reduce the design and implementation difficulty of a local oscillator link, and meanwhile greatly reduce the cost of the whole receiver. Theoretically, the smaller the harmonic order is, the lower the frequency conversion loss and the noise coefficient become, but, the higher the local oscillator frequency is, the harder the implementation becomes, and thus, performance and implementation of the mixer need to be comprehensively considered for n selection. A mixer at the frequency band of 325 GHz-500 GHz covers a WR2.2 standard waveguide frequency band, is widely applied to test instruments at the frequency band of 325 GHz-500 GHz and is commonly a first order of the receiver. Thus, how to realize low frequency conversion loss, noise temperature and other performance indexes in the broadband becomes a key for improving the performance of the terahertz test instruments. The local oscillator frequency needed for fourth-harmonic mixing at the frequency band of 325 GHz-500 GHz is only 81.25 GHz-125 GHz, meanwhile, a fourth harmonic is not essentially changed compared with a second harmonic under a broadband condition, which becomes one of preferred schemes for the broadband receiver at the frequency band, particularly in an aspect of application of a terahertz test instrument receiver. The inventor of the present disclosure finds that some researchers have designed, by a circuit topology shown in FIG. 1, a fourth-harmonic mixer at the frequency band of 430 GHz-480 GHz. A topological circuit mainly includes five parts: a radio frequency signal coupled transmission unit 104, a nonlinear device (anti-parallel diodes) 105, a radio frequency low pass filter 106, a local oscillator signal coupled transmission unit 107, an intermediate frequency filter unit 108, etc. According to the circuit topology shown in FIG. 1, a single radio frequency loop is adopted in the whole circuit, and in addition, a GND in the loop is far away from the nonlinear device, which causes difficult local oscillator harmonic clutter signal matching. Meanwhile, a local oscillator signal filter unit adopts a high-low impedance line resonance unit, which is poor in bandwidth and restraint character, difficultly eliminates influences from local oscillator signals, and cannot meet design requirements of the broadband mixer.

### SUMMARY

To overcome the defects in the prior art, the present disclosure provides a broadband terahertz fourth-harmonic mixer circuit, a mixer and a method, which effectively solve the problem about implementation of low frequency conversion loss in a wide frequency band of 325 GHz-500 GHz, guarantee realization of a high-performance and low-cost receiver at 325 GHz-500 GHz, and meet requirements of a high-performance test instrument at the frequency band of 325 GHz-500 GHz.

To achieve the foregoing objective, the present disclosure uses the following technical solutions:

A first aspect of the present disclosure provides a broadband terahertz fourth-harmonic mixer circuit.

The broadband terahertz fourth-harmonic mixer circuit includes a radio frequency signal coupled transmission unit, a nonlinear device, a local oscillator filter, a local oscillator signal coupled transmission unit and an intermediate frequency filter unit which are sequentially connected; and
further includes a radio frequency input port, a local oscillator input port and an intermediate frequency output port, where the radio frequency input port is connected to the radio frequency signal coupled transmission unit, the local oscillator input port is connected to the local oscillator signal coupled transmission unit, the intermediate frequency output port is connected to an output end of the intermediate frequency filter unit, and the local oscillator filter is of a two-level cascaded filter structure.

As some possible implementations, a cutoff frequency of two-level cascaded filters is 125 GHz and 250 GHz respectively.

As some possible implementations, the radio frequency signal coupled transmission unit is connected to a radio frequency probe for grounding, and near ends of nonlinear anti-parallel diodes are grounded.

As some possible implementations, the local oscillator filter and an intermediate frequency filter each adopt a Harmmer head filter.

As some possible implementations, the radio frequency input port and the local oscillator input port each adopt a waveguide transmission line structure.

A second aspect of the present disclosure provides a broadband terahertz fourth-harmonic mixer.

The broadband terahertz fourth-harmonic mixer includes the mixer circuit according to the first aspect of the present disclosure, and the mixer circuit is arranged on a substrate.

As some possible implementations, a minimum line width of a circuit conduction band is 10 microns.

As some possible implementations, the substrate includes, but is not limited to, one of a quartz substrate and a gallium arsenide substrate.

A third aspect of the present disclosure provides a working method of a broadband terahertz fourth-harmonic mixer.

The working method of the broadband terahertz fourth-harmonic mixer utilizes the terahertz fourth-harmonic mixer according to the second aspect of the present disclosure and includes the following steps:
receiving the radio frequency signals at the frequency band of 325 GHz-500 GHz and the local oscillator signals at the frequency band of 81.25 GHz-125 GHz;
grounding near ends of anti-parallel diodes for mixing to reduce ground loop influences and improve broadband matching characters;
restraining a second harmonic, a third harmonic and a fourth harmonic in a local oscillator frequency through a two-level cascaded local oscillator filter; and
outputting intermediate frequency signals through an intermediate frequency output port.

Compared with the prior art, the present disclosure has the following beneficial effects:

1. By means of the circuit, the mixer and the method according to the present disclosure, the second harmonic, the third harmonic and the fourth harmonic of the local oscillator frequency are restrained through the two-level cascaded local oscillator filter, which, on one hand, improves an isolation degree between the mixer local oscillator and the radio frequency, and on the other hand, reduces influences of local oscillator harmonic signals on implementation of mixer broadband and low frequency conversion loss performance.

2. The circuit, the mixer and the method according to the present disclosure solve the contradiction problem of mutual restraint between the broadband and the low frequency conversion loss, effectively solve the problem about realization of low frequency conversion loss in a wide frequency band of 325 GHz-500 GHz, guarantee realization of the high-performance and low-cost receiver at 325 GHz-500 GHz, and meet requirements of the high-performance test instrument at the frequency band of 325 GHz-500 GHz.

3. The circuit, the mixer and the method according to the present disclosure adopt a dual-ground structure, which firstly retains a radio frequency probe GND shown in FIG. 1, and secondly adds a near end GND at anti-parallel diodes for mixing, thereby reducing ground loop influences and improving broadband matching characters.

4. By means of the circuit, the mixer and the method according to the present disclosure, the local oscillator and the intermediate frequency filter each adopt the Harmmer head structure, which has a smaller size and reduces loss of signals in a transmission process.

5. The circuit, the mixer and the method according to the present disclosure can realize the low frequency conversion loss in the terahertz broadband, provide a solution for a terahertz broadband and high-cost-performance terahertz broadband receiver, and lay a firm foundation for the high-performance terahertz test instrument and detection devices.

6. The circuit, the mixer and the method according to the present disclosure achieve an objective that the frequency conversion loss of the fourth-harmonic mixer at the full frequency band of 325 GHz-500 GHz is 15 dB-22 dB, and the loss is low.

### BRIEF DESCRIPTION OF THE DRAWINGS

The accompanying drawings constituting a part of the present disclosure are used to provide further understanding of the present disclosure. Exemplary embodiments of the present disclosure and descriptions thereof are used to explain the present disclosure, and do not constitute an improper limitation to the present disclosure.

FIG. 1 is a schematic structural diagram of an existing mixer circuit according to a background art of the present disclosure.

FIG. 2(a) is a schematic structural diagram of a terahertz fourth-harmonic mixer circuit according to an embodiment 1 of the present disclosure.

FIG. 2(b) is a local amplifying circuit of a mixer circuit topology dual-ground structure according to the embodiment 1 of the present disclosure.

FIG. 2(c) is a local amplifying circuit of two-level filtering in a mixer circuit topology according to the embodiment 1 of the present disclosure.

FIG. 2(d) is an overall implementation circuit design sketch of the fourth-harmonic mixer at the frequency band of 325 GHz-500 GHz according to the embodiment 1 of the present disclosure.

FIG. 3 is a test chart of the fourth-harmonic mixer at the frequency band of 325 GHz-500 GHz according to the embodiment 1 of the present disclosure.

FIG. 4 is a schematic comparison diagram of broadband out-of-band stray restraining situations by two-level filtering according to the embodiment 1 of the present disclosure.

FIG. 5(a) is a schematic diagram of influences of the dual-ground structure on radio frequency transmission according to the embodiment 1 of the present disclosure.

FIG. 5(b) is a schematic diagram of influences of the dual-ground structure on mixer frequency conversion loss performance according to the embodiment 1 of the present disclosure.

FIG. 6 is a schematic comparison diagram of frequency conversion loss design and implementation situations of the fourth-harmonic mixer at the frequency band of 325 GHz-500 GHz according to the embodiment 1 of the present disclosure.

101—Radio frequency input port; 102—local oscillator input port; 103—intermediate frequency output port; 104—radio frequency signal coupled transmission unit; 105—nonlinear device; 106—radio frequency low pass filter; 107—local oscillator signal coupled transmission unit; 108—intermediate frequency filter unit; 109—grounding probe;

201—Radio frequency input port; 202—local oscillator input port; 203—intermediate frequency output port; 204—radio frequency signal coupled transmission unit; 205—nonlinear anti-parallel diode and match unit; 206—local oscillator filter; 207—local oscillator signal coupled transmission unit; 208—intermediate frequency filter unit; 209—grounding probe; 210—second GND; 211—first filter; 212—second filter; 213—diode; 214—intermediate frequency filter element;

301—Frequency doubler; 302—frequency tripler; 303—fourth-harmonic mixer at 325 GHz-500 GHz; 304—intermediate frequency signal output end; 306—source module at 325 GHz-500 GHz; 307—spectrum analyzer; 308—first microwave signal generator; and 309—second microwave signal generator.

### DETAILED DESCRIPTION

The present disclosure is further described below with reference to the accompanying drawings and embodiments.

It should be noted that the following detailed descriptions are all exemplary and are intended to provide a further description of the present disclosure. Unless otherwise specified, all technical and scientific terms used herein have the same meaning as commonly understood by a person of ordinary skill in the technical field to which the present disclosure belongs.

It should be noted that terms used herein are only for describing specific implementations and are not intended to limit exemplary implementations according to the present disclosure. As used herein, the singular form is intended to include the plural form, unless the context clearly indicates otherwise. In addition, it should further be understood that terms “comprise” and/or “include” used in this specification indicate that there are features, steps, operations, devices, components, and/or combinations thereof.

The embodiments in the present disclosure and features in the embodiments may be mutually combined in case that no conflict occurs.

### Embodiment 1

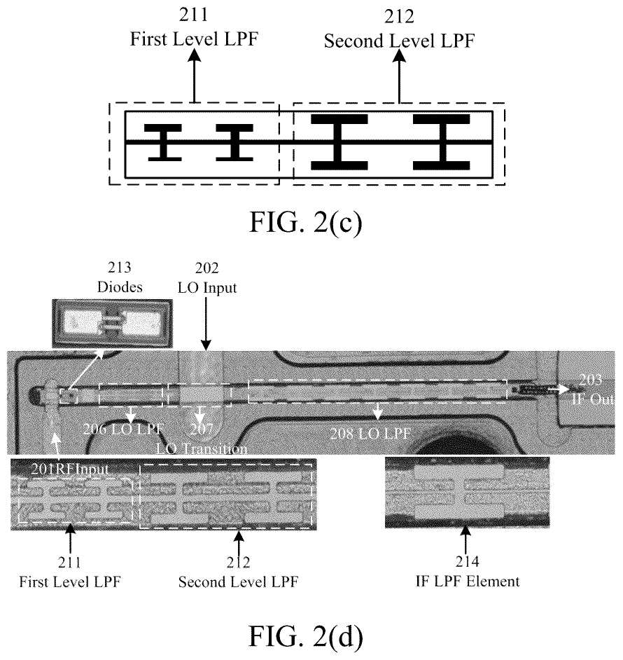

The embodiment 1 of the present disclosure provides a broadband terahertz fourth-harmonic mixer. FIG. 2(a) illustrates the circuit topology of the broadband terahertz fourth-harmonic mixer provided by the embodiment, meanwhile, design verification is performed at the frequency band of 325 GHz-500 GHz, and a technical index that the frequency conversion loss within the full frequency band of 325 GHz-500 GHz is less than 22 dB is realized.

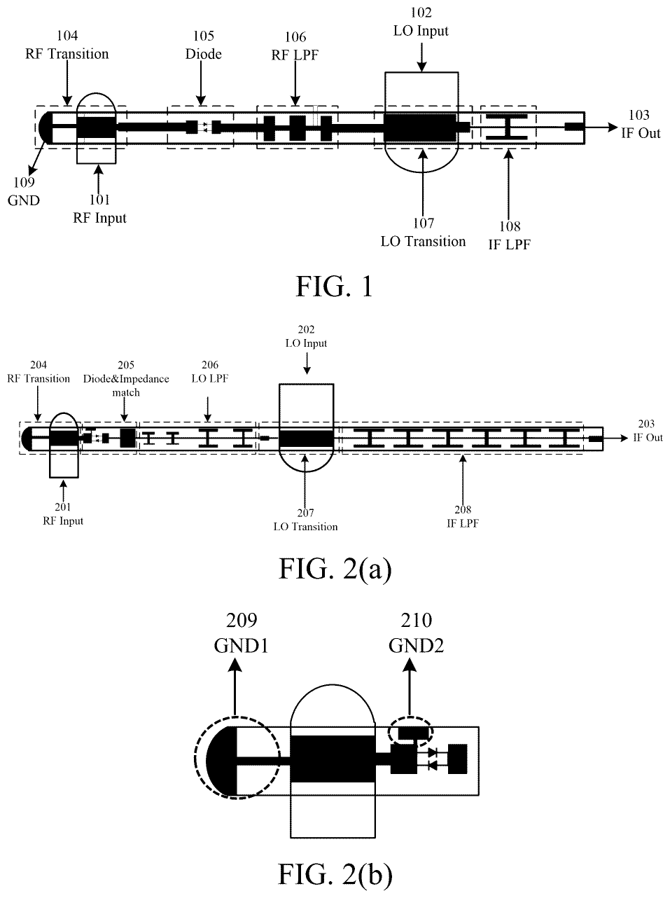

Compared with a result based on FIG. 1, an objective of the low frequency conversion loss is realized within the broadband, thereby effectively solving the problem about realizing a broadband and high-performance receiver in a test instrument of 325 GHz-500 GHz.

Specifically, FIG. 2(a) is an overall implementation topology of the fourth-harmonic mixer. FIG. 2(b) is a local amplifying circuit of a mixer circuit topology dual-ground structure. FIG. 2(c) is a local amplifying circuit of two-level filtering in the mixer circuit topology. FIG. 2(d) is an overall implementation circuit of the fourth-harmonic mixer with the frequency band being 325 GHz-500 GHz.

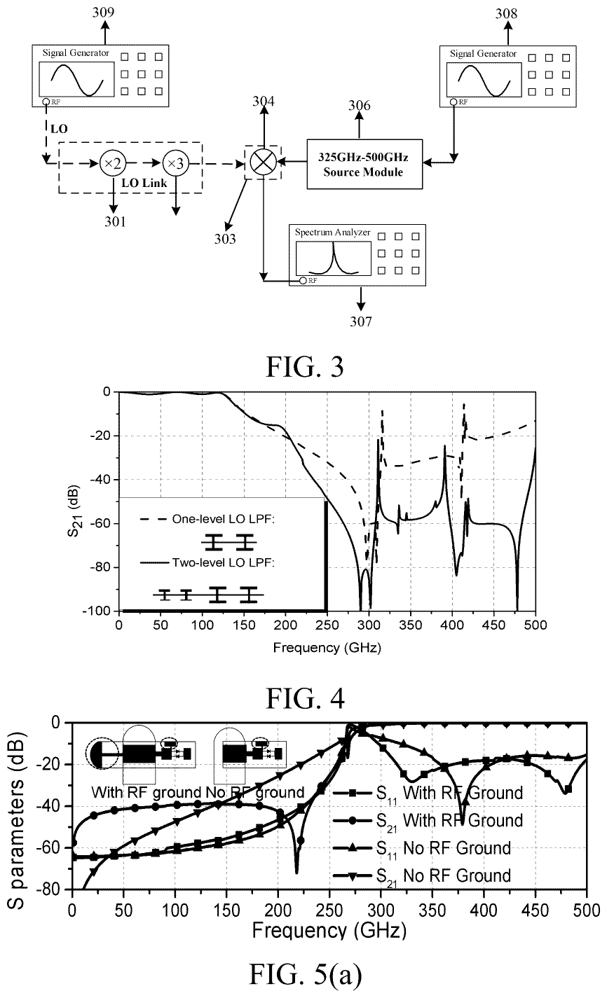

FIG. 3 is a test chart of the fourth-harmonic mixer at the frequency band of 325 GHz-500 GHz. Local oscillator signals at the frequency band of 81.25 GHz-125 GHz are generated by adopting sixth frequency multiplication.

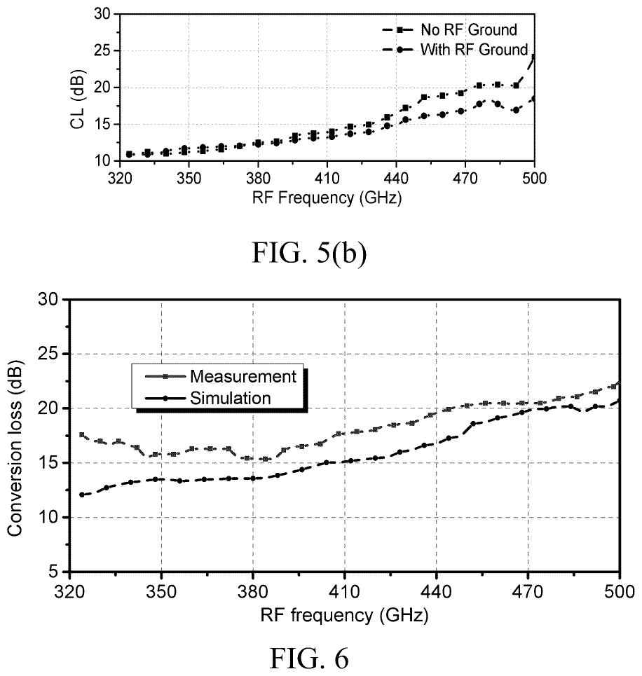

FIG. 4 illustrates a comparison of broadband out-of-band stray restraining situations through two-level filtering. FIG. 5(a) illustrates influences of the dual-ground structure on radio frequency transmission. FIG. 5(b) illustrates influences of the dual-ground structure on mixer frequency conversion loss performance. FIG. 6 illustrates a comparison between frequency conversion loss design and an implementation situation of the fourth-harmonic mixer at the frequency band of 325 GHz-500 GHz, designed according to the manner of the embodiment. It can be seen from data that frequency conversion loss is less than 22 dB within the full frequency band of 325 GHz-500 GHz, and meanwhile the design value and the implementation value have high consistency. The mixer provided by the embodiment can effectively solve the technical problem about mutual restraint between broadband and high efficiency of the terahertz fourth-harmonic mixer, and lays a firm foundation for high-cost-performance terahertz test instruments, terahertz detection devices, etc.

The terahertz fourth-harmonic mixer circuit provided by the embodiment, as shown in FIG. 2(a), includes a radio frequency input port 201, a local oscillator input port 202 and an intermediate frequency output port 203, where the radio frequency input port 201 and the local oscillator input port 202 each adopt a waveguide transmission line structure; and includes a radio frequency signal coupled transmission unit 204, a nonlinear anti-parallel diode and match unit 205, a local oscillator filter 206, a local oscillator signal coupled transmission unit 207 and an intermediate frequency filter unit 208.

As shown in FIG. 2(c), a local oscillator and an intermediate frequency filter each adopt a Harmmer head structure, which has a smaller size and can reduce loss in a signal transmission process. Meanwhile, to restrain spurious signals of local oscillator signals, a two-level filter structure shown in FIG. 2(c) is adopted and includes a first filter 211 and a second filter 212 with cut-off frequency being 125 GHz and 250 GHz respectively. FIG. 4 illustrates a design result. It can be seen that the two-level filtering cascade structure can realize in-broadband high harmonic restraint at 200 GHz-500 GHz, an isolation degree of the fourth-harmonic mixer of 325 GHz-500 GHz is improved, meanwhile, influences on the mixer from the clutter signals are reduced, and realization of broadband and low-conversion-loss performance of the fourth-harmonic mixer of 325 GHz-500 GHz is guaranteed.

In addition, it should be particularly noted that according to the dual-ground structure design provided by the embodiment, one GND is close to diodes and is a second GND 210, and the other GND is a probe GND 209 on the radio frequency transmission unit shown in FIG. 2(b). A distributed multi-loop circuit topology form is adopted, which reduces ground loop influences and improve broadband matching characters.

FIG. 5(a) and FIG. 5(b) illustrate comparisons of theoretical design results. The performance of the mixer is obviously improved, particularly, at the frequency band of 375 GHz-500 GHz, thereby effectively guaranteeing realization of broadband and high performance at 325 GHz-500 GHz.

FIG. 2(d) is the fourth-harmonic mixer at the frequency band of 325 GHz-500 GHz, manufactured according to the manner of the embodiment. The circuit adopts a 50-micron quartz substrate. A minimum line width of a circuit conduction band is only 10 microns. Diodes 213 and an intermediate frequency filter element 214 are shown.

It is to be understood that in some other implementations, the substrate may also be a gallium arsenide substrate, which can be selected by those skilled in the art according to specific working conditions, and thus unnecessary details are not given herein.

The fourth-harmonic mixer at 325 GHz-500 GHz designed according to the manner of the embodiment is tested as shown in FIG. 3. A frequency doubler 301 and a frequency tripler 302 constitute a local oscillator link of the fourth-harmonic mixer 303 at 325 GHz-500 GHz and are matched with a first microwave signal generator 309 to generate local oscillator signals at the frequency band of 81.25 GHz-125 GHz. Radio frequency signals at the frequency band of 325 GHz-500 GHz are generated by a second microwave signal generator 308 and a source module 306 at 325 GHz-500 GHz. Intermediate frequency signals are outputted by an intermediate frequency signal output end 304 and analyzed and tested by a spectrum analyzer 307.

### Embodiment 2

The embodiment 1 of the present disclosure provides a working method of a broadband terahertz fourth-harmonic mixer, which utilizes the terahertz fourth-harmonic mixer according to the embodiment 1 of the present disclosure and includes the following steps:
receiving the radio frequency signals at the frequency band of 325 GHz-500 GHz and the local oscillator signals at the frequency band of 81.25 GHz-125 GHz;
grounding near ends of anti-parallel diodes for mixing to reduce ground loop influences and improve broadband matching characters;
restraining a second harmonic, a third harmonic and a fourth harmonic in a local oscillator frequency through a two-level cascaded local oscillator filter; and
outputting intermediate frequency signals through an intermediate frequency output port.

A person skilled in the art should understand that the embodiments of the present disclosure may be provided as a method, a system, or a computer program product. Therefore, the present disclosure may use a form of hardware embodiments, software embodiments, or embodiments combining software and hardware. In addition, the present disclosure may use a form of a computer program product implemented on one or more computer-usable storage media (including but not limited to a disk memory, an optical memory, etc.) including computer-usable program code.

The present disclosure is described with reference to flowcharts and/or block diagrams of the method, the device (system), and the computer program product in the embodiments of the present disclosure. It is to be understood that computer program instructions can implement each procedure and/or block in the flowcharts and/or the block diagrams and a combination of procedures and/or blocks in the flowcharts and/or the block diagrams. These computer program instructions may be provided to a general-purpose computer, a dedicated computer, an embedded processor, or a processor of another programmable data processing device to generate a machine, so that the instructions executed by the computer or the processor of the another programmable data processing device generate an apparatus for implementing a specific function in one or more processes in the flowcharts and/or in one or more blocks in the block diagrams.

These computer program instructions may also be stored in a computer-readable memory that can instruct a computer or another programmable data processing device to work in a specific manner, so that the instructions stored in the computer-readable memory generate a manufactured article that includes an instruction apparatus. The instruction apparatus implements a specific function in one or more procedures in the flowcharts and/or in one or more blocks in the block diagrams.

These computer program instructions may further be loaded onto the computer or the another programmable data processing device, so that a series of operation steps are performed on the computer or the another programmable device, thereby generating computer-implemented processing. Therefore, the instructions executed on the computer or the another programmable device provide steps for implementing the specific function in one or more procedures in the flowcharts and/or in one or more blocks in the block diagrams.

A person of ordinary skill in the art may understand that all or some of the procedures of the methods of the foregoing embodiments may be implemented by a computer program instructing relevant hardware. The program may be stored in a computer-readable storage medium. When the program is executed, the procedures of the foregoing method embodiments may be implemented. The foregoing storage medium may be a magnetic disc, an optical disc, a Read-Only Memory (ROM) or a Random Access Memory (RAM), or the like.

The foregoing descriptions are merely exemplary embodiments of the present disclosure, but are not intended to limit the present disclosure. The present disclosure may include various modifications and changes for a person skilled in the art. Any modification, equivalent replacement, or improvement made within the spirit and principle of the present disclosure shall fall within the protection scope of the present disclosure.

1. A broadband terahertz fourth-harmonic mixer circuit, comprising a radio frequency signal coupled transmission unit, a nonlinear device, a local oscillator filter, a local oscillator signal coupled transmission unit and an intermediate frequency filter unit which are sequentially connected; and
further comprising a radio frequency input port, a local oscillator input port and an intermediate frequency output port, wherein the radio frequency input port is connected to the radio frequency signal coupled transmission unit, the local oscillator input port is connected to the local oscillator signal coupled transmission unit, the intermediate frequency output port is connected to an output end of the intermediate frequency filter unit, and the local oscillator filter is of a two-level cascaded filter structure.

2. The terahertz fourth-harmonic mixer circuit according to claim 1, wherein a cutoff frequency of two-level cascaded filters is 125 GHz and 250 GHz respectively.

3. The terahertz fourth-harmonic mixer circuit according to claim 1, wherein the radio frequency signal coupled transmission unit is connected to a radio frequency probe for grounding, and near ends of nonlinear anti-parallel diodes are grounded.

4. The terahertz fourth-harmonic mixer circuit according to claim 1, wherein the local oscillator filter and an intermediate frequency filter each adopt a Harmmer head filter.

5. The terahertz fourth-harmonic mixer circuit according to claim 1, wherein the radio frequency input port and the local oscillator input port each adopt a waveguide transmission line structure.

6. A broadband terahertz fourth-harmonic mixer, comprising the mixer circuit according to claim 1, wherein the mixer circuit is arranged on a substrate.

7. The terahertz fourth-harmonic mixer according to claim 6, wherein a minimum line width of a circuit conduction band is 10 microns;
or, the substrate comprises, but is not limited to, one of a quartz substrate and a gallium arsenide substrate.

8. The terahertz fourth-harmonic mixer according to claim 6, wherein a frequency doubler and a frequency tripler constitute a local oscillator link and are matched with a first signal generator to generate local oscillator signals at a frequency band of 81.25 GHz-125 GHz.

9. The terahertz fourth-harmonic mixer according to claim 6, wherein radio frequency signals at a frequency band of 325 GHz-500 GHz are generated by a second signal generator and a source module at 325 GHz-500 GHz.

10. A working method of a broadband terahertz fourth-harmonic mixer, utilizing the terahertz fourth-harmonic mixer according to claim 6 and comprising the following steps:
receiving the radio frequency signals at the frequency band of 325 GHz-500 GHz and the local oscillator signals at the frequency band of 81.25 GHz-125 GHz;
grounding near ends of anti-parallel diodes for mixing to reduce ground loop influences and improve broadband matching characters;
restraining a second harmonic, a third harmonic and a fourth harmonic in a local oscillator frequency through a two-level cascaded local oscillator filter; and
outputting intermediate frequency signals through an intermediate frequency output port.
